(19) United States
(12) Patent Application Publication
(10) Pub. No.: US 2024/0321623 A1
(43) Pub. Date: Sep. 26, 2024

(54) MOUNTING TOOL AND MOUNTING APPARATUS

(71) Applicant: SHIBAURA MECHATRONICS CORPORATION, Yokohama-shi (JP)

(72) Inventor: Yoshihiro KUSUBE, Yokohama-shi (JP)

(73) Assignee: SHIBAURA MECHATRONICS CORPORATION, Yokohama-shi (JP)

(21) Appl. No.: 18/613,488

(22) Filed: Mar. 22, 2024

(30) Foreign Application Priority Data
Mar. 24, 2023 (JP) 2023-048708
Feb. 14, 2024 (JP) 2024-020398

(51) Int. Cl. H01L 21/683; H01L 21/687

(52) U.S. Cl. CPC H01L 21/6838; H01L 21/68785

(57) ABSTRACT

According to one embodiment, a mounting tool and a mounting apparatus that can be used for the electronic components with different sizes without changing a shape thereof and can reduce remaining air bubbles when mounting the electronic component on the substrate are provided. A mounting tool 31 of the embodiment includes: a holder 311 including a holding surface 311a configured to hold an inner side of the electronic component 2 inside a pair of opposite outer edges of the electronic component 2; an expanded portion 312 including an opposing surface that is facing away from an overhang portion 2c of the electronic component 2 that protrudes outward than the outer edge of the holding surface 311a of the holder 311 and is not held by the holder 311; a first opening 313 provided in the holding surface 311a; a second opening 315 provided in the opposing surface 312a; a first ventilation path 314 configured to communicate with the first opening 313 and to suck and hold the electronic component 2 at the holding surface 311a by creating negative internal pressure; and a second ventilation path 316 that sucks the overhang portion 2c of the electronic component 2 facing the opposing surface 312a by creating negative internal pressure.

### CROSS-REFERENCE TO RELATED APPLICATION

This application is based upon and claims the benefit of priority from Japan Patent Application No. 2023-048708, filed on Mar. 24, 2023, the entire contents of which are incorporated herein by reference.

### FIELD OF INVENTION

The present disclosure relates to a mounting tool and a mounting apparatus.

### BACKGROUND

To mount electronic components that are semiconductor elements, such as logics, memories, and image sensors, on a substrate, a wafer on which the semiconductor elements are formed are cut into individual chips. Then, the chips are picked up one by one and are transferred and mounted on the substrate.

When mounting the electronic components, air bubbles may remain between the electronic components and the substrate. The air bubbles present between the electronic components and the substrate may cause poor connection and lack of strength, leading to mounting failure. To address this, when mounting the electronic components, a mounting tool to crimp the electronic components on the substrate mounts the electronic components by holding the electronic component so that the electronic component is curved to follow the curved surface, contacting a part of the electronic component to the substrate, then pressing the electronic component by an elastic body, and pressing out gas between the electronic component and the substrate.

### SUMMARY OF INVENTION

### Problems to be Solved by Invention

However, since the shape of the curvature of the electronic component varies depending on the size of the electronic component, to curve the electronic component along the curved surface as described above, mounting tools with different curved shapes have to be prepared to match the electronic component.

The present disclosure is provided to address the above-described problem, and the objective is to provide a mounting tool and a mounting apparatus that can be used for the electronic components with different sizes without changing a shape thereof and that can reduce remaining air bubbles when mounting the electronic component on the substrate.

### Means to Solve the Problem

An embodiment of the present disclosure is a mounting tool to mount a rectangular electronic component on a substrate, and includes:
a holder including a holding surface configured to hold an inner side of the electronic component inside a pair of opposite outer edges of the electronic component;
an expanded portion including an opposing surface that is facing away from an overhang portion of the electronic component that protrudes outward than the outer edge of the holding surface of the holder and is not held by the holder;
a first opening provided in the holding surface;
a second opening provided in the opposing surface;
a first ventilation path configured to communicate with the first opening and to suck and hold the electronic component at the holding surface by creating negative internal pressure; and
a second ventilation path configured to communicate with the second opening and to suck the overhang portion of the electronic component facing the opposing surface by creating negative internal pressure.

The mounting apparatus of an embodiment includes:
a tool moving mechanism that moves the mounting tool in a direction in which the electronic component contacts with or separate away from a mounting target;
a first switch configured to switch presence or absence of the negative pressure in the first ventilation path; and
a second switch configured to switch presence or absence of the negative pressure in the second ventilation path.

### Effect of Invention

The mounting tool and the mounting apparatus of the present disclosure can be used for the electronic components with different sizes without changing a shape thereof and can reduce remaining air bubbles when mounting the electronic component on the substrate.

### BRIEF DESCRIPTION OF DRAWINGS

FIG. 1 is a front view illustrating the mounting apparatus according to the embodiment.

FIG. 2 is a plan view illustrating the mounting apparatus according to the embodiment.

FIG. 3A is a side view, FIG. 3B is a bottom view, and FIG. 3C is a cross-sectional view illustrating the mounting tool according to the embodiment.

FIG. 4 is a functional block diagram the controller according to the embodiment.

FIG. 5 is a flowchart illustrating the procedures to mount the electronic component according to the embodiment.

FIGS. 6A-6D are explanatory diagrams illustrating an aspect of mounting the electronic component according to the embodiment.

FIG. 7A is a cross-sectional view illustrating suction of the electronic component by the conventional mounting tool, and FIG. 7B is a cross-sectional view illustrating the electronic component in contact with the substrate.

FIG. 8A is a plan view illustrating the electronic component used in the experiment, and FIG. 8B is a side view illustrating the mounting tool.

FIGS. 9A and 9B are graphs indicating deformation of the electronic component by the experiment.

FIGS. 10A and 10B are graphs indicating deformation of the electronic component by the experiment.

FIGS. 11A and 11B are graphs indicating deformation of the electronic component by the experiment.

FIG. 12 is a bottom view illustrating a modified example of the mounting tool in which the first opening is a groove.

FIG. 13 is a side view illustrating a modified example of the mounting tool in which the holding surface is a curved surface.

FIG. 14 is a cross-sectional view illustrating a case in which there is a portion in the holding surface that does not contact with the held surface of the electronic component.

### EMBODIMENTS

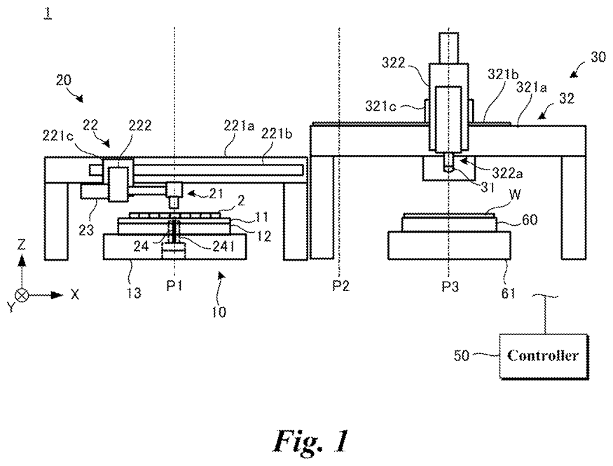

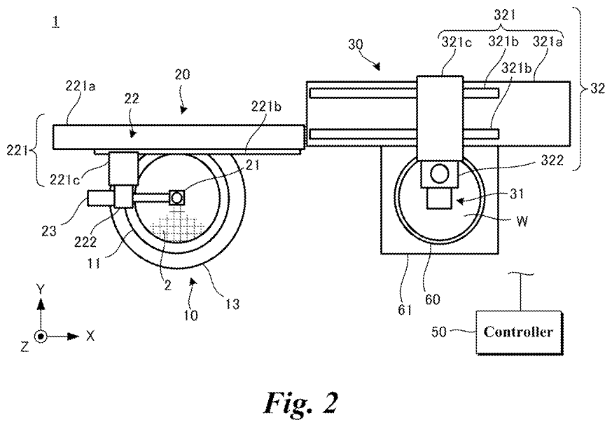

A mounting apparatus of the embodiments is described in detail with the reference to the figures. Note that the figures are schematic and include portions with exaggerated size and ratio to ease the understanding thereof. As illustrated in FIGS. 1 and 2, a mounting apparatus 1 includes a supplier 10, a pickup device 20, a mounting device 30, and a controller 50, and is an apparatus to pick up a rectangular electronic component 2 from the supplier 10 by the pickup device 20, transfer the electronic component 2 to the mounting device 30, and mount the electronic component 2 on a substrate W supported by a substrate stage 60 using the mounting device 30. The rectangular electronic component 2 is an electronic component 2 with rectangular shape formed by rectangular faces. For example, the electronic component 2 is a chip component, In the present embodiment, the electronic component 2 is a semiconductor chip formed by dividing a wafer into individual pieces and is a rectangular plate.

### [Supplier]

The supplier 10 is a device to supply the electronic component 2 to the pickup device 20. The supplier 10 moves the electronic component 2 that is a pickup target to a supply position P1. The supply position P1 is a position where the pickup device 20 picks up the electronic component 2 that is the pickup target. The supplier 10 includes a supply stage 12 to support a sheet 11 on which the electronic component 2 is attached, and a stage moving mechanism 13 to move the supply stage 12. For example, the stage moving mechanism 13 is a ball screw mechanism driven by a servomotor.

The sheet 11 attached on the electronic component 2 is a wafer sheet with stickiness attached on an unillustrated wafer ring. A plurality of the electronic components 2 is arranged in the sheet 11 in a matrix (row). In the present embodiment, the electronic component 2 is arrange in face-up state in which a functional surface is exposed upward.

The supply stage 12 is a base to horizontally support the wafer ring on which the sheet 11 is attached. That is, the supply stage 12 supports the sheet 11 on which the electronic component 2 is attached via the wafer ring. The supply stage 12 is movable in the horizontal direction by the stage moving mechanism 13. Since the sheet 11 is supported horizontally by the stage moving mechanism 13 together with the supply stage 12, the sheet 11 and the electronic component 2 on said sheet 11 is also movable in the horizontal direction. By this, the supplier 10 moves and positions the electronic component 2 that is the pickup target among the plurality of the electronic components 2 to the supply position P1.

Note that, as illustrated in FIGS. 1 and 2, in the horizontal direction, the horizontal direction in which the supplier 10 and the mounting device 30 align is the X direction and the horizontal direction orthogonal to the X direction is the Y direction. Also, the direction orthogonal to the plane of the sheet 11 is the Z direction or the vertical direction. The upward direction is the direction at a side where the electronic component 2 is placed on the plane of the sheet 11 as a boundary, and the downward direction is the direction at a side where the electronic component 2 is not placed on the plane of the sheet 11 as a boundary.

The pickup device 20 is a relay device that picks up the electronic component 2 from the supplier 10 and delivers the picked up electronic component 2 to the mounting device 30. This pickup device 20 includes a pickup nozzle 21, a nozzle moving mechanism 22, a direction changer 23, and a push-up pin 24.

The pickup nozzle 21 is a cylindrical suction nozzle that holds the electronic component 2 and releases the electronic component 2 by releasing the holding state. The pickup nozzle 21 has a nozzle hole opened on a suction surface at the end. The nozzle hole is communicates with a negative-pressure generation apparatus (unillustrated) such as a vacuum pump, and sucks and holds the electronic component 2 at the nozzle hole by the negative pressure generated by said apparatus. Furthermore, by releasing the negative pressure by the negative-pressure generation apparatus, the electronic component 2 is released from the pickup nozzle 21.

The nozzle moving mechanism 22 is a mechanism to reciprocally move the pickup nozzle between the supply position P1 and the delivery position P2 and to ascend and descend the supply position P1 and the delivery position P2. In detail, the nozzle moving mechanism 22 includes a sliding mechanism 221 and an elevation mechanism 222. Note that the delivery position P2 is a position where the pickup device 20 delivers the electronic component 2 picked up at the supply position P1 to the mounting tool 31 acting as a receiver, which is described later.

The supply position P1 and the delivery position P2 mainly define position in the horizontal direction (XY direction) and do not necessarily define the vertical direction (Z direction). Furthermore, even if said positions define the position (height) in the Z direction, said height has predetermined width. The predetermined width includes the thickness of the electronic component 2, the distance to push-up the electronic component 2, and the distance which the electronic component 2 can sucked and the like, when the electronic component 2 is delivered.

The sliding mechanism 221 reciprocally moves the pickup nozzle 21 between the supply position P1 and the delivery position P2. Here, the sliding mechanism 221 includes a rail 221b fixed to a support frame 221a and extending in parallel with the X direction, and a slider 221c sliding on the rail 221b. The slider 221c is driven using a ball screw driven by an unillustrated rotary motor, and linear motor, etc.

The elevation mechanism 222 moves the pickup nozzle 21 up and down. In detail, the elevation mechanism 222 may utilize a ball screw mechanism driven by a servomotor. That is, the servomotor drives the pickup nozzle 21 to ascend or descend along the Z direction. This elevation mechanism 222 is attached to the slider 221c of the sliding mechanism 221.

The direction changer 23 is provided between the pickup nozzle 21 and the nozzle moving mechanism 22. Here, the direction changer 23 is an actuator including a driving source for motors to change the direction of the pickup nozzle 21, and a rotary guide such as ball bearings. Change the direction means to rotate in the vertical direction by 0 to 180 degrees. For example, the pickup nozzle 21, in which the suction surface is facing downward to the supply stage 12, sucks and holds the electronic component 2 at the supply position P1. Then, the direction changer 23 changes the direction of the pickup nozzle 21 so that the suction surface faces upward. At this time, the rotation degree is 180 degrees.

The push-up pin 24 is provided below the sheet 11 of the supplier 10 at the supply position P1. The push-up pin 24 is a needle-shaped member with a pointed tip. The push-up pin 24 is provided inside a backup body 241 so that the length direction thereof becomes in parallel with the Z direction.

The backup body 241 includes driving mechanism to advance or retract the push-up pin 24 relative to the interior thereof. This advancement or retraction is performed vertically. For example, the driving mechanism is a mechanism driven by an air cylinder and cum mechanism. Furthermore, the backup body 241 is connected to the unillustrated negative-pressure circuit and sucks and holds the sheet 11.

### [Mounting Device]

The mounting device 30 is an apparatus to transport the electronic component 2 received from the pickup device 20 to the mounting position P3 and mount the electronic component 2 on a substrate W. The mounting position P3 is a position to mount the electronic component 2 on the substrate W. The mounting device 30 includes a mounting tool 31 and a tool moving mechanism 32.

### [Mounting Tool]

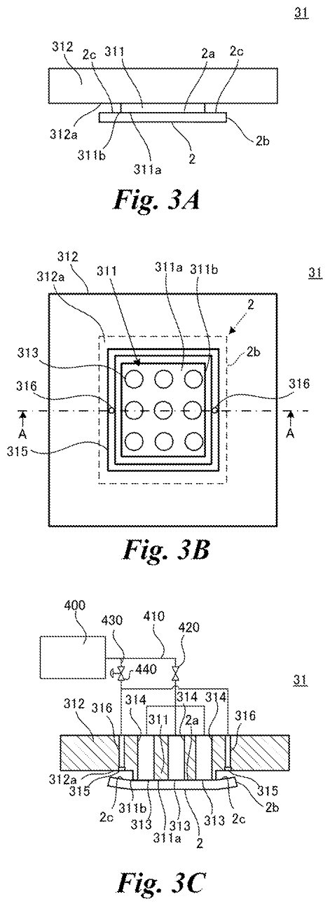

The mounting device 31 is a component that acts as a receiver to receive the electronic component 2 from the pickup nozzle 21 at the deliver position P2 and that mounts the electronic component 2 on a substrate W at the mounting position P3. The mounting tool 31 sucks and holds the electronic component 2 by the negative pressure caused by the unillustrated negative-pressure circuit and releases the negative pressure after the mounting to release the electronic component 2. In detail, as illustrated in FIGS. 3A, 3B, and 3C, the mounting tool 31 has a rectangular shape, and includes a holder 311 and an expanded portion 312. Note that FIG. 3A is a side view illustrating the mounting tool 31 sucking and holding the electronic component 2. FIG. 3B is a bottom view thereof and FIG. 3C is a side view thereof.

### (Holder)

The holder 311 is a rectangular plate that resembles the electronic component 2. The holder 311 includes a holding surface 311a to hold the electronic component 2. The holding surface 311a is a plane surface formed on the bottom surface of the holder 311.

The size of the holding surface 311a is smaller than the electronic component 2. That is, the size of the holding surface 311a is smaller than a held surface 2a of the electronic component 2 (in the present embodiment, the upper surface of the electronic component 2 that is the functional surface). By this, the holding surface 311a holds the inner side of the electronic component 2 inside an outer edge 2b positioned at the supply position P1. That is, the holder 311 holds the electronic component 2 so that the outer edge 311b of the holding surface 311a is at the inner side than the outer edge 2b of the electronic component 2. At this time, the holder 311 may hold the inner side of the electronic component 2 at least inside a pair of the opposite outer edges 2b. In the present embodiment, as illustrated in FIG. 3B, the holder 311 holds the electronic component 2 so that entire circumference of the outer edge 311b of the holding surface 311a is at the inner side than entire circumference of the outer edge 2b of the electronic component 2. Note that, in FIG. 3B, the electronic component 2 is indicated by the dotted line.

Accordingly, since the holder 311 holds the inner side of the electronic component 2 inside the outer edge 2b, a portion that protrudes from the outer edge 311b of the holding surface 311a is produced in the electronic component 2, because the held surface 2a does not overlap the holding surface 311a. This protruding portion is called an overhang portion 2c.

It is preferable that the mounting tool 31 is formed of rigid material, so that the holder 311 does not elastically deform by the pressure when mounting the electronic component 2. Although the holding surface 311a of the present embodiment is rectangular (including square and rectangle), any shape may be employed if the electronic component 2 can be held as described above.

### (Expanded Portion)

An expanded portion 312 has a portion that is facing away from the overhang portion 2c of the electronic component 2 by protruding outward than the outer edge 311b of the holding surface 311a of the holder 311a. The expanded portion 312 of the present embodiment is a rectangular plate provided on the upper surface of the holder 311. A opposing surface 312a is a surface facing the overhang portion 2c of the expanded portion 312. Not entire surface of the opposing surface 312a have to face the overhang portion 2c if there is a portion facing the overhang portion 2c.

Furthermore, the mounting tool 31 includes a first opening 313, a first ventilation path 314, a second opening 315, and a second ventilation path 316. The first opening 313 is a hole provided in the holding surface 311a. A plurality of the first openings 313 is provided in the holding surface 311a. As illustrated in FIG. 3B, the plurality of the first openings 31 are arranged in matrix.

The first ventilation path 314 is communicated with the first opening 313 and sucks and holds the electronic component 2 using the holding surface 311a by creating negative internal pressure. As illustrated in FIG. 3C, a negative-pressure generation device 400 to generate negative pressure such as a vacuum pump is communicated with the first ventilation path 314 via a piping 410 and a switch 420. The switch 420 is a valve acting as a first switch to switch the presence and absence of the negative pressure relative the first ventilation path 314.

The second opening 315 is a linear groove provided in the opposing surface 312a. The second opening 315 is a rectangular frame surrounding the holder 311. The second opening 315 is facing the overhang portion 2c of the electronic component 2.

The second ventilation path 316 is communicated with the second opening 315 and sucks the overhang portion 2c facing the opposing surface 312a by creating negative internal pressure. By this the overhang portion 2c at the periphery of the electronic component 2 warps and deforms. FIG. 3C is a cross-sectional view of FIG. 3B and illustrates the sucked electronic component 2 in which the portion contacting with the holding surface 311a is held flat and the overhang portion 2c is deformed. The second ventilation path 316 is provided at the center of a pair of sides of the second opening 315. The negative-pressure generation device 400 to generate negative pressure is communicated with the second ventilation path 316 via the piping 430 and an adjuster 440. The adjuster 440 is a valve acting as a second switch to switch the presence and absence of the negative pressure relative to the second ventilation path 316 and also acting as an adjuster to adjust the suction force by exhaustion.

### [Tool Moving Mechanism]

The tool moving mechanism 32 reciprocally moves the mounting tool 31 between the deliver position P2 and the mounting position P3, and ascends and descends the mounting tool 31 at the deliver position P2 and the mounting a position P3. The tool moving mechanism 32 includes sliding mechanism 321 and an elevation mechanism 322.

The sliding mechanism 321 reciprocally moves the mounting tool 31 between the delivery position P2 and the mounting position P3. Here, the sliding mechanism 321 includes a rail 321b fixed to a support frame 321a and extending in parallel with the X direction, and a slider 321c sliding on the rail 321b. Note that, although unillustrated, the sliding mechanism 321 includes a sliding mechanism to slide the mounting tool 31 in the Y direction. This sliding mechanism may also be formed by a rail in the Y direction and a slider sliding on the rail.

The elevation mechanism 322 vertically moves the mounting tool 31 by driving an arm removably provided in the mounting tool 31. In detail, the elevation mechanism 322 may utilize a ball screw mechanism driven by a servomotor. That is, the servomotor drives the mounting tool 31 to ascend or descend along the Z direction. Furthermore, a detector to detect the contact of the mounting tool 31 to the substrate W is provided in the elevation mechanism. Load sensors such as a strain gauge or a piezoelectric element may be used for the detector 322a.

The substrate stage 60 is a stage to support the substrate W on which the electronic component 2 is mounted. The substrate stage 60 is provided on a stage moving mechanism 61. The stage moving mechanism 61 is a moving mechanism to slide the substrate stage 60 on the XY plane and match the substrate stage 60 with the mounting position P3 for the electronic component 2 in the substrate W. For example, the stage moving mechanism 61 is a ball screw mechanism driven by a servomotor.

### [Controller]

The controller 50 controls start, stop, speed, and operation timing of the supplier 10, the pickup device 20, the mounting device 30, and the substrate stage 60. That is, the controller 50 is a control device of the mounting apparatus 1. For example, the controller 50 can be implements by dedicated electronic circuits or computers operated by predetermined programs, etc. The controller 50 is connected to an input device for operators to input instruction and information necessary for control and an output device to check status of the devices. Switches, touch panels, keyboards, and mouses may be used for the input device. Displays such as liquid crystal and organic EL may be used for the output device.

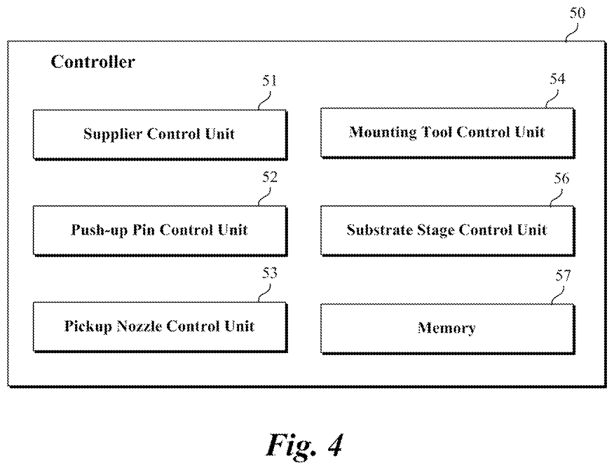

FIG. 4 is a functional block diagram of the controller 50. The controller 50 includes a supplier control unit 51, a push-up pin control unit 52, a pickup nozzle control unit 53, a mounting tool control unit 54, a substrate stage control unit 56, and a memory 57.

The supplier control unit 51 controls the movement of the supply stage 12. That is, the supplier control unit 51 controls the movement of the electronic component 2 that is the pickup target placed on the sheet 11. The push-up pin control unit 52 controls the movement of the push-up pin 24.

The pickup nozzle control unit 53 controls the movement of the pickup nozzle 21, that is, the operation of the nozzle moving mechanism 22 and the direction changer 23. Furthermore, the pickup nozzle control unit 53 controls the negative-pressure generation device communicated with the nozzle hole and controls the holding and releasing of the electronic component 2.

The mounting tool control unit 54 controls the movement of the mounting tool 31, that is, the operation of the tool moving mechanism 32. Furthermore, the mounting tool control unit 54 controls the negative-pressure generation device 400 communicated with the first ventilation path 314 and the second ventilation path 316 of the mounting tool 31, the switch 420, and the adjuster 440, and controls the holding and releasing, and a curve of the electronic component 2 by adjusting the presence and absence of the negative pressure at the first opening 313 and the second opening 315, and the suction pressure at the second opening 315. Furthermore, the mounting tool control unit 54 controls the switching of the presence and absence of the negative pressure in the first ventilation path 314 and the second ventilation path 316 according to the contact detection by the detector 322a. The substrate stage control unit 56 controls the movement of the substrate stage 60, that is, the operation of the stage moving mechanism 61.

The memory 57 is a storage medium such as HDD or SSD. The memory 57 stores data and programs necessary for the operation of the mounting apparatus 1 in advance and stores data necessary for the operation of the mounting apparatus 1. For example, the necessary data is supply position P1, the deliver position P2, position coordinates of the mounting position P3, and position coordinates of each moving mechanism. Each of the moving mechanism controls the movement of respective structures based on these coordinates. Furthermore, the memory 57 stores timings to switch the presence and absence of the negative pressure in the first ventilation path 314 and the second ventilation path 316 of the mounting tool 31, and the suction pressure by the negative pressure.

### [Action]

The operation of the mounting device 1 above will be described. Firstly, the pickup device 20 picks up the electronic component 2 from the supplier 10 and delivers said electronic component 2 to the mounting device 30. That is, the pickup device 20 moves the pickup nozzle 21 to the supply position P1 where the push-up pin 24 is positioned so that the nozzle hole of the pickup nozzle 21 and the push-up pin 24 faces with each other.

Meanwhile, the supplier 10 moves the supply stage 12 to position the electronic component 2 that is a pickup target to a supply position P1. Then, the pickup device 20 descends the pickup nozzle 21 so that the suction surface contacts with the electronic component 2 at the supply position P1 and sucks the electronic component 2. Then, the pickup nozzle 21 picks up the electronic component 2 by peeling off the electronic component 2 from the sheet 11 as the push-up pin 24 pushes up the electronic component 2 while rising while holding the electronic component 2.

The pickup device 20 turns the pickup nozzle 2 over by the direction changer 23. That is, the direction of the pickup nozzle 21 is rotated 180 degrees in the vertical direction to direct the suction surface of the pickup nozzle 21 upward. Note that the pickup nozzle may be turned over at any position between the supply position P1 and the deliver position P2.

The pickup device 20 moves the picked up electronic component 2 to the deliver position P2 by the nozzle moving mechanism 22. The mounting tool 31 of the mounting device 30 moves to and waits at the deliver position P2 by the tool moving mechanism 32 so that the nozzle hole of the pickup nozzle 21 and the holding surface 311a of the mounting tool 31 faces with each other via the electronic component 2.

Then, the mounting tool 31 descends toward the pickup nozzle 21 positioned at the deliver position P2, the switch 420 applies the negative pressure in the first ventilation path 314 of the mounting tool 31, the holding surface 311a sucks and holds the electronic component 2 by the negative pressure applied to the first opening 313, and then the pickup nozzle 21 releases the negative pressure. By this, the electronic component 2 delivers from the pickup nozzle 21 to the mounting tool 31.

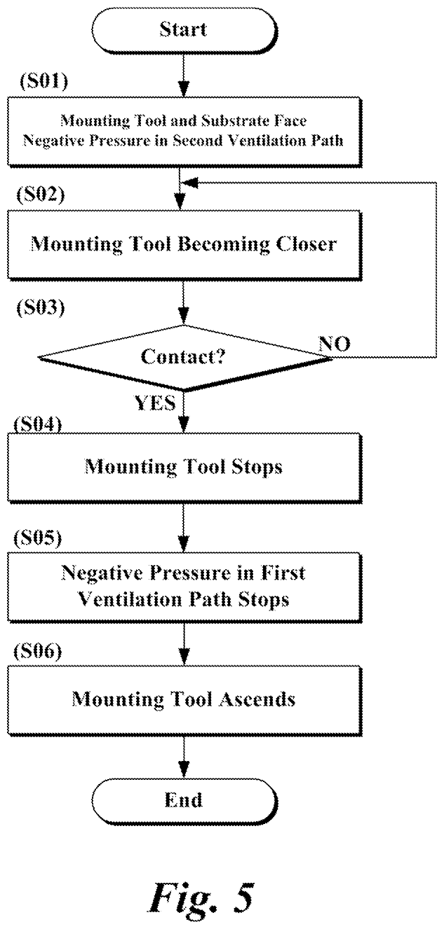

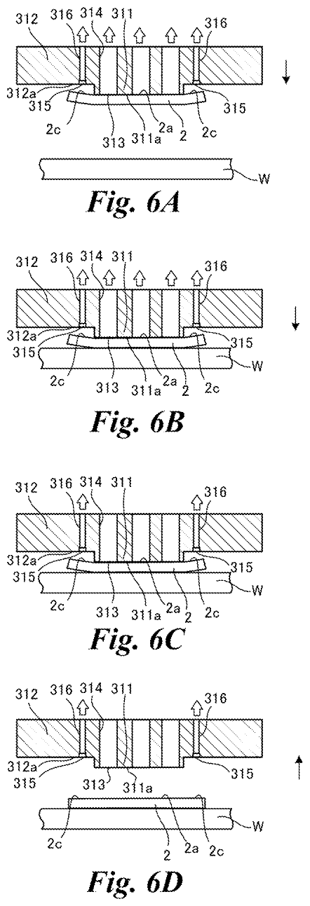

Then, the mounting tool 31 moves to the mounting position P3 and mounts the electronic component 2 on the substrate W. This mounting operation will be described by referring to the flowchart of FIG. 5 and the operation description of FIGS. 6A-6D. Firstly, the mounting tool 31 moves to the mounting position P3, and as illustrated in FIG. 6A, the electronic component 2 held by the mounting tool 31 faces the substrate W (Step S01). At this time, the adjuster 440 applies the negative pressure in the second ventilation path 316 of the mounting tool 31m and since the overhang portion 2c of the electronic component 2 is sucked by the negative pressure applied in the second opening 315, the periphery of the electronic component 2 deforms. That is, the periphery of the electronic component 2 curves toward the sucked direction. In the present embodiment, since the second opening 315 sucks the periphery of the electronic component 2 from above, the periphery of the electronic component 2 curves upward. Then, the mounting tool 31 descends and the electronic component 2 comes closer to the substrate W (Step S02).

As illustrated in FIG. 6B, when the detector 322a detects that the electronic component 2 is in contact with the substrate W (Step S03, YES), the mounting tool 31 stops descending (Step S04). The portion of the electronic component 2 pressed onto the substrate W by the holding surface 311a is crimped to the substrate W, but the portion of the electronic component 2 curved by the negative pressure of the second ventilation path 316 is not crimped to the substrate W. That is, the periphery of the electronic component that is curved upward is not crimped on the substrate W.

Then, as illustrated in FIG. 6C, the switch 420 stops the negative pressure of the first ventilation path 314 (Step S05). Furthermore, as illustrated in FIG. 6D, the mounting tool 31 ascends and is evacuated from the substrate W, leaving the electronic component 2 (Step S06). Accordingly, the suction force to the overhang portion 2c of the electronic component 2 is no longer effective, and the curved periphery of the electronic component 2 gradually flattens outward to follow the flat surface of the substrate W, so that air bubbles are eliminated outward, and the electronic component 2 is mounted on the substrate W.

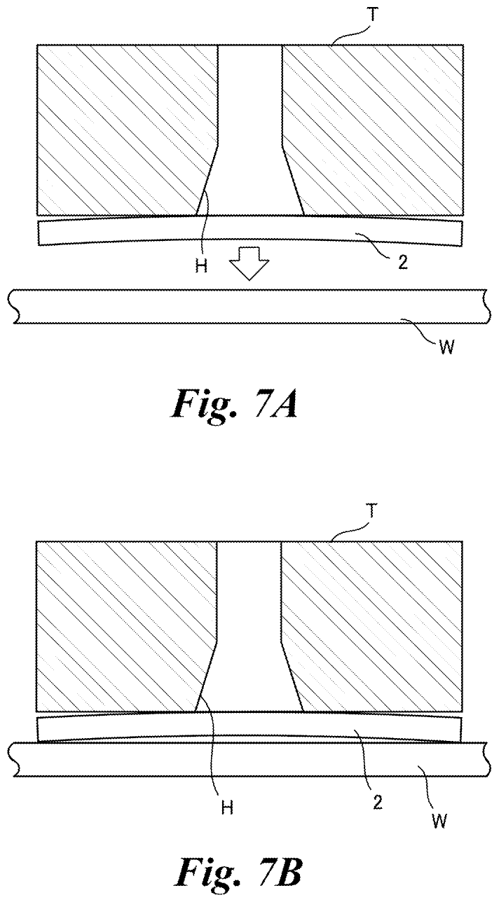

For example, as illustrated in FIGS. 7A and 7B, in the case of the conventional mounting tool T, the length of the electronic component 2 in the horizontal direction and the length of the contact surface of the mounting tool T in the horizontal direction is the same. Since the suction hole H is formed in the center of the contact surface of the mounting tool T, the electronic component 2 is sucked and held at a position near the center of the electronic component 2. As illustrated in FIG. 7A, when the mounting tool sucks and holds the electronic component 2 in this state, a gap is formed between the periphery of the contact surface of the mounting tool T and the periphery of the electronic component 2, because the suction force is not applied on the periphery of the electronic component 2. That is, the periphery of the electronic component 2 curves downward so that it hangs down with the sucked portion at the center of the electronic component 2 as the fulcrum.

As illustrated in FIG. 7B, when the mounting tool T descends to mount the electronic component 2 on the substrate W in this state, the periphery of the electronic component 2 contacts with the substrate W first. Then, the mounting tool T further presses the electronic component 2 onto the substrate W, so that portions of the electronic component 2 other than the periphery contacts with the substrate W. However, in this case, since the periphery of the electronic component 2 contacts with the substrate W first, space is produced between the portions of the electronic component 2 other than the periphery and the substrate W. When such space is produced, air easily gets into said space. If the mounting tool T presses the electronic component 2 onto the substrate W and the portions of the electronic component 2 other than the periphery contacts with the substrate W in this state, they are joined with the air bubbles there between. Even when the mounting tool T is pressed, air bubbles cannot escape, because the periphery of the electronic component 2 is joined first. That is, air bubbles remain, resulting in poor connection.

Accordingly, the periphery of the electronic component 2 contacts and joins to the substrate W first, which means that air bubbles are captures in the joining process. In contrast, in the present embodiment, the mounting tool T holds the electronic component 2 so that the periphery of the electronic component 2 is curved upward, and in this state, the flat surface of the electronic component 2 other than the periphery is contacted and joined to the substrate W. By this, since the flat surface of the electronic component 2 and the flat surface of the substrate W are joined, it becomes difficult for the gap into which air bubbles enter to be produced, and air bubbles are suppressed from remaining.

Furthermore, when the center of the contact surface of the mounting tool T is protruded, such as when the contact surface is protruding downward or has a semicircular shape, the contact surface of the mounting tool T contacts, sucks and holds the center of the electronic component faster than the periphery of the electronic component 2. Also in this case, the periphery of the electronic component 2 curves downward so that it hangs down with the sucked portion at the center of the electronic component 2 as the fulcrum, so that the periphery of the electronic component 2 joins to the substrate W first, and air bubbles cannot escape and remain, resulting in poor connection.

Furthermore, the hanging down of the periphery of the electronic component 2 can be prevented by providing a suction hole H at the periphery of the flat contact surface of the mounting tool T. However, in this case, since the center and periphery of the electronic component 2 contact with the substrate W almost at the same time, a path for air bubbles to escape is blocked, resulting in poor connection. In the present embodiment, the overhang portion 2c of the electronic component 2 is sucked to prevent hanging down, so that path for air bubbles to escape is created, and therefore, the poor connection to the substrate W can be prevented.

### EXAMPLES

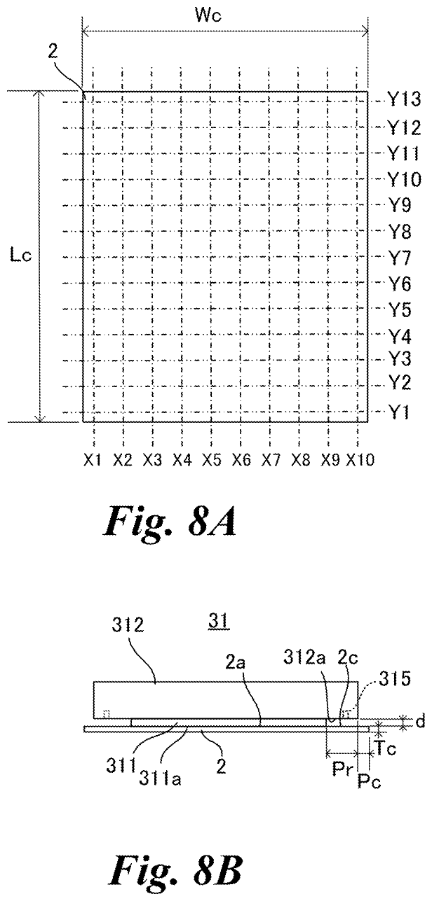

The test result in which the sucked and held electronic component 2 is deformed using the mounting tool 31 of the embodiment is described. As illustrate in FIGS. 8A and 8B, the electronic component 2 used was a rectangular semiconductor chip with the width Wc=9 mm, the height Lc=12 mm, and the thickness Tc=0.1 mm.

The opposing surface 312a protruding outward from the holder 311 of the mounting tool 31 had the protrusion length Pr parallel to the holding surface 311a of 1.5 mm. Furthermore, the protrusion length Pc protruding outward from the expanded portion 312 of the electronic component 2 held by the holder 311 was 0.5 mm. The thickness of the holder 311, that is, the distance between the opposing surface 312a and the overhang portion 2c which had not deformed was 0.01 mm.

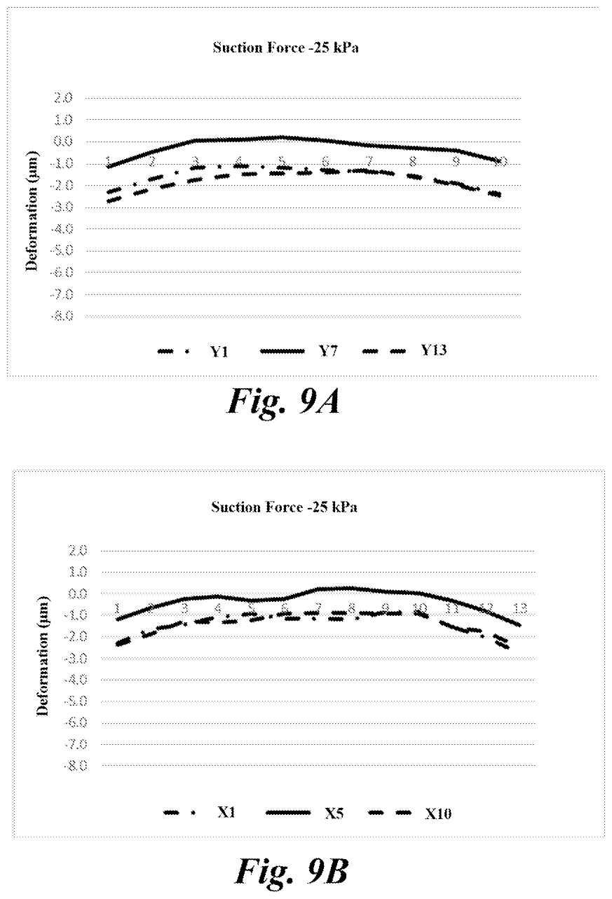

In the test, in a state the electronic component 2 was sucked and held on the holding surface 311a by the negative pressure of the first ventilation path 314, the deformation amount of the electronic component 2 when the electronic component 2 when the suction pressure of the second ventilation path 316 was changed to 25 kPa, 50 kPa, 75 kPa was measured using a white confocal displacement sensor. The result is shown in FIGS. 9 to 11. Numbers (horizontal axis) of 1 to 10 in FIGS. 9A, 10A, and 11A correspond to the rows X1 to X10 of the electronic component 2 shown in FIG. 8A. The solid line indicates the deformation amount at the rows X1 to X10 on the center column Y7, and the dotted line and dash line indicates the deformation amount at the rows X1 to X10 on the columns Y1 and Y13 near both ends. Numbers (horizontal axis) of 1 to 13 in FIGS. 9B, 10B, and 11b correspond to the columns Y1 to Y13 of the electronic component 2 shown in FIG. 8A, and the solid line indicates the deformation amount at the columns Y1 to Y13 on the center row X5, and the dotted line and dash line indicates the deformation amount at the columns Y1 to Y13 on the rows X1 and X10 near both ends.

Therefore, FIGS. 9A, 10a, and 11a show the profile in the width direction in FIG. 8 of the electronic component 2, and FIGS. 9B, 10B, and 11B show the profile in the vertical direction in FIG. 8 of the electronic component 2. Note that the graphs in FIGS. 9 to 11 was the height of the surface of the electronic component 2 measured from the lower side (electronic-component-2 side) in FIG. 8B. A negative value of the deformation in the vertical axis indicates that the electronic component 2 deformed in the expanded-portion-312 side. The positions of X1, X10, Y1, and Y13 were located within 0.5 mm, which is the protrusion length PC, inward from the end of each side of the electronic component 2. Generally, they were located at the end of each side of the expanded portion 312. The end of each side of the opposing surface 312a was proximal to X2, X9, Y2, and Y12.

As illustrated in FIGS. 9 to 11, it was found that the periphery of the electronic component 2 can be deformed to curve by sucking the overhang portion 2c. Furthermore, it was found that the deformation amount can be adjusted by changing the suction pressure.

For example, in FIG. 9A, X1 and X10 had deformed by approximately 1 μm relative to the center (X5, X6, Y6 to Y8) at all of the positions Y1, Y7, and Y13. In contrast, the deformation amount at the position X3 to X8 was approximately 0.5 μm at all of the positions Y1, Y7, and Y13, meaning that they were flatly sucked and held by the flat surface of the holder 311. As shown in FIG. 9B, this state was the same in the vertical direction of the electronic component 2. That is, by applying the suction pressure of −25 kPa to the periphery of the electronic component 2 with the thickness of 0.1 mm at the distance of 0.01 mm, the portion of the electronic component 2 held by the holder 311 is kept flat and the periphery at the four sides of the electronic component 2 was deformed to curve.

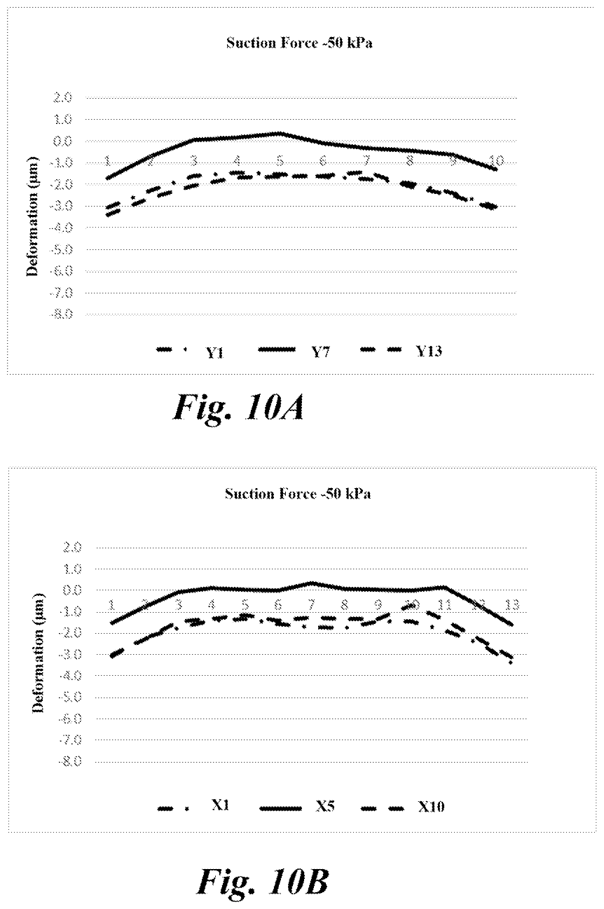

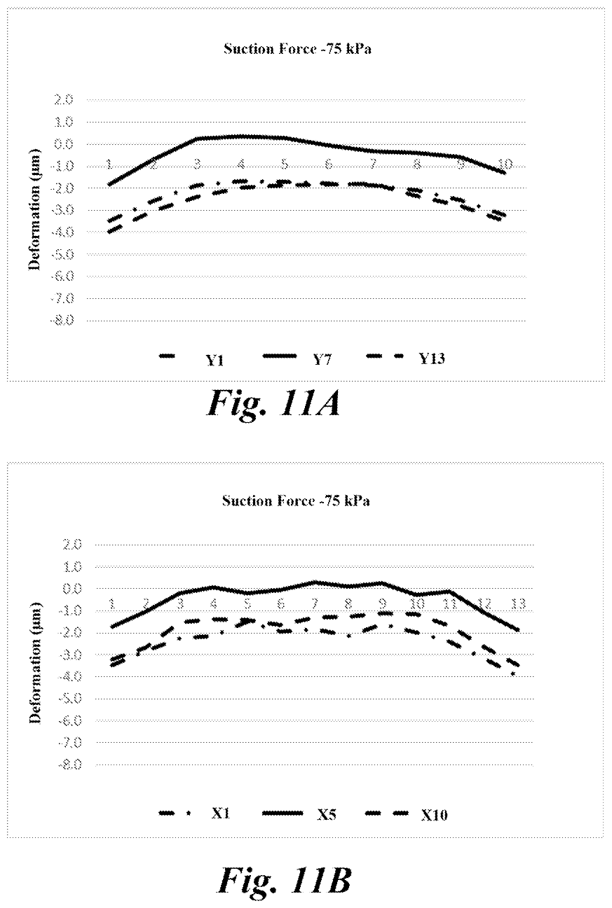

Furthermore, as shown in FIGS. 10A and 10B, this state was the same when the suction pressure of −50 kPa was applied. In this case, the periphery of the electronic component 2 was deformed by approximately 1 to 2 μm. Furthermore, as shown in FIGS. 11A and 11B, this state was the same when the suction pressure of −75 kPa was applied, and the periphery of the electronic component 2 was deformed by approximately 2 μm. That is, the deformation amount was controlled by controlling the suction pressure. Furthermore, in all of the suction pressure, the electronic component 2 was held flat by the holding surface 311a of the holder 311.

Note that, in all of the suction pressure, the periphery of the electronic component 2 did not deform when the thickness (Tc) of the electronic component 2 was 0.2 mm or more. Accordingly, the present embodiment can be implemented for the electronic component 2 with the thickness of 0.2 mm or less.

### [Effect]

(1) The present embodiment is a mounting tool 31 to mount a rectangular electronic component 2 on a substrate W, and includes: a holder 311 including a holding surface 311a configured to hold an inner side of the electronic component 2 inside a pair of opposite outer edges 2b of the electronic component 2; an expanded portion 312 including an opposing surface that is facing away from an overhang portion 2c of the electronic component 2 that protrudes outward than the outer edge 311b of the holding surface 311a of the holder 311 and is not held by the holder 311; a first opening 313 provided in the holding surface 311a; a second opening 315 provided in the opposing surface 312a; a first ventilation path 314 configured to communicate with the first opening 313 and to suck and hold the electronic component 2 at the holding surface 311a by creating negative internal pressure; and a second ventilation path 316 configured to communicated with the second opening 315 and to suck the overhang portion 2c of the electronic component 2 facing the opposing surface 312a by creating negative internal pressure.

Furthermore, the mounting apparatus 1 of present embodiment includes: a tool moving mechanism 32 that moves the mounting tool 31 in a direction in which the electronic component 2 contacts with or separate away from a mounting target; first switch (switch 420) that switches presence or absence of the negative pressure in the first ventilation path 314; and a second switch (switch 440) that switches presence or absence of the negative pressure in the second ventilation path 316.

Therefore, the electronic component 2 that is the mounting target can be contacted with the substrate W by the tool moving mechanism 32 in a state in which the electronic component 2 is sucked and held on the holding surface 311a by the negative pressure of the first ventilation path 314, while the portion of the electronic component 2 facing the opposing surface 312a is sucked by the negative pressure of the second ventilation path 316 to deform the electronic component 2. That is, the portion of the electronic component 2 other than the periphery is held by the opposing surface 312a and the overhang portion 2c that is the periphery of the electronic component 2 is sucked and curved to contact the portion other than the periphery to the substrate W first. Then, the negative pressure of the first ventilation path 314 is stopped to release the suction and holding, and the curved periphery of the electronic component 2 is released from the suction force of the second ventilation path 316 by releasing the electronic component 2 from the mounting tool 31. In the process of flattening the periphery of the electronic component 2 to follow the substrate W, the electronic component 2 is mounted so that air bubble can be discharged from the center area of the electronic component 2. By this, air bubbles are suppressed from remaining between the electronic component 2 and the substrate W, reducing the mounting failure. Accordingly, since the electronic component 2 can be deformed by controlling the negative pressure of the second ventilation path 316, not depending on the shape of the holding surface 311a, the electronic components 2 with different size can be mounted without changing the shape of the mounting tool 31. Thus, there is no need to prepare different mounting tool 31 depending on various types of the electronic components 2.

(2) The opposing surface 312a faces the electronic component 2 sucked by the negative pressure of the second ventilation path 316 without contact. That is, the opposing surface is provided at a position where the periphery of the electronic component 2 curving upward does not become in contact. Therefore, the curve amount of the electronic component 2 is not restricted by contacting with the opposing surface 312a, such that the curve amount is not restricted and the apparatus can be implemented for various type of the electronic components 2. However, the present embodiment is not limited to the case in which the opposing surface does not contact with the sucked electronic component 2, and the case in which there is a contact is included.

(3) The holding surface 311a is a flat surface. Since the overhang portion 2c of the periphery of the electronic component 2 faces the substrate W with a gap, air bubbles can easily escape from this gap, and since the center portion of the electronic component 2 is held flat by the holding surface 311a, the load does not concentrate on the electronic component 2, suppressing damage to the electronic component 2. That is, when the pressing of the electronic component 2 starts from contacting points, lines, and areas of a part of the electronic component 2, the pressing force concentrates on the narrow range, causing damage, however, in the present embodiment, since the electronic component 2 contacts the substrate W on the flat surface, the damage is suppressed. Also, the apparatus can be implemented for the electronic component 2 with various size, without forming a specific curved surface on the holding surface 311a. Since the shape of the mounting tool 31 becomes simple, the manufacturing becomes easy.

(4) The second opening 315 is a linear groove provided in the expanded portion 312. Therefore, the negative pressure can be applied over a large area. In the present embodiment, the linear groove is a frame surrounding the holder 311. Therefore, the negative pressure can be applied over the entire circumference of the overhang portion 2c.

(5) The mounting apparatus 1 includes an adjuster 440 to adjust the negative pressure relative to the second ventilation path 316. Thus, the negative pressure to obtain the desired curve can be applied according to the size of the electronic component 2.

(6) The mounting apparatus 1 includes a detector 322a to detect the contact of the mounting tool 31 to the substrate W, and when the detector 322a detects the contact, the first switch stops the negative pressure of the first ventilation path 314, and then the tool moving mechanism 32 releases the mounting tool 31 from the substrate W while the second switch maintaining the negative pressure of the second ventilation path 316. Thus, the curve of the periphery of the electronic component 2 is maintained when contacting the electronic component 2 to the substrate W, and when the mounting tool 31 is released, the electronic component 2 is mounted so as to follow the substrate W.

### Modified Example

The present embodiment may be implemented as the below modified examples.

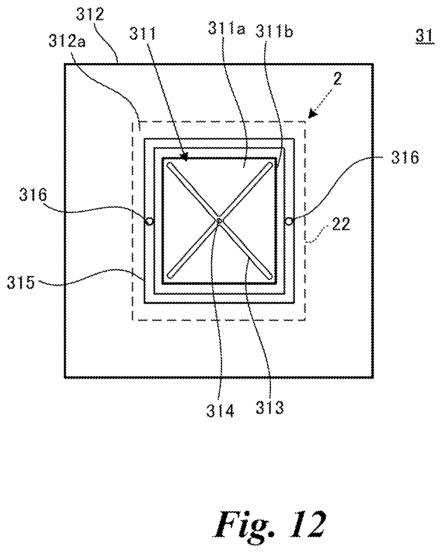

(1) the first opening 313 may be a linear groove. For example, as illustrated in FIG. 12, the first opening 313 is a X-shaped groove formed on the diagonal of the holding surface 311a. The first ventilation path 314 is provided at the intersection of the X-shaped groove. However, the four ends of the first opening 313 do not reach the corners of the holding surface 311a. By this, wide range can be sucked and held while keeping the number of the first ventilation path 314 minimum. However, the four ends of the first opening 313 must not reach the corners of the holding surface 311a. By this, the suction for the periphery of the electronic component 2 and the suction for the holding can be separated.

(2) The second opening 315 may be a plurality of holes communicated with the second ventilation path 316. Furthermore, the expanded portion 312 may protrude only from a part of the outer circumference of the holder 311, not the entirety thereof if the expanded portion 312 includes the opposing surface 312a provided in the second opening 315 communicated with the second ventilation path 316.

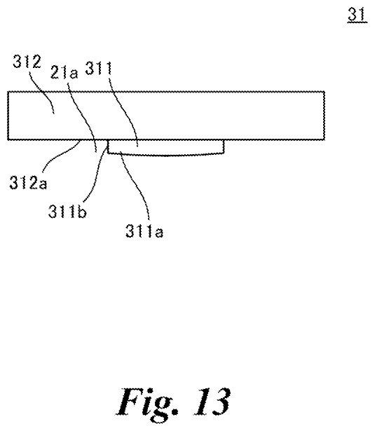

(3) The holding surface 311a may be a curved surface. For example, as illustrated in FIG. 13, the holding surface 311a may have a shape that protrudes like a part of the side of the cylinder or a part of the side of the sphere. Note that, a part of the side of the cylinder here includes the cases in which they are a part of the cylinder with the cross-section of circle, oval, rectangle with round corners, and track-shape. By this, the curve at the periphery of the electronic component 2 becomes gentle, and the affect to the electronic component 2 can be suppressed. Thus, even when the holding surface 311a is a curved surface, the electronic components 2 with different sizes can be employed because the holding surface 311a is small.

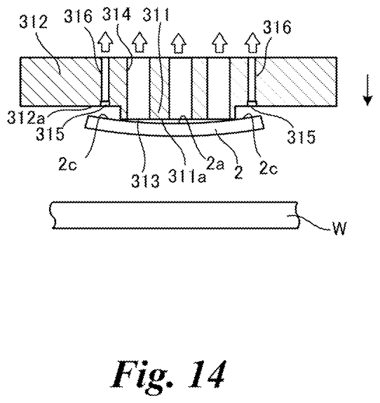

(4) As illustrated in FIG. 14, the affect to the electronic component 2 is suppressed even when there is a portion where the held surface 2a electronic component 2 does not contact with the holding surface 311a when the periphery of the electronic component 2 is sucked. That is, unlike the case in which a part of the holding surface 311a is protruded so that the pressing force concentrates, since the electronic component 2 itself held by the holding surface 311a is deformed, creates gap, and is mounted to follow the substrate W, the load does not concentrate on a part of the electronic component 2, and the affect to the electronic component 2 is suppressed. However, if the center of the electronic component 2 is close to the holding surface 311a and becomes concaved, it is preferable closely contact the held surface 2a to the holding surface 311a, because air bubbles may remain in said center.

(5) When the detector 322a detects the contact, the first switch may stop the negative pressure of the first ventilation path 314, and then the second switch may stop the negative pressure of the second ventilation path 316, and the tool moving mechanism 32 may release the electronic component 2. Also by this, the curve of the electronic component 2 is maintained when contacting the electronic component 2 to the substrate W so as not block discharge of air bubbles, and by stopping the suction of periphery of the electronic component 2 from said state, the electronic component 2 may follow the substrate W. That is, even when ways to hold and release the electronic component 2b by the mounting tool 31 is changed, since ways the electronic component 2 contacts and follows the substrate W is the same, the electronic component 2 can be mounted without obstructing the discharge of air bubbles.

### Other Embodiment

Note that the present disclosure is not limited to the above embodiments, and other aspects indicating the above may be included. Furthermore, the present disclosure includes aspects that is combinations of all or some of the above embodiment and other embodiments. Moreover, these new embodiments may be implemented in other various forms, and various omission, replacement, range, and change may be performed without departing from an abstract of the invention.

### REFERENCE SIGN

1: mounting apparatus
2: electronic component
2a: held surface
2b: outer edge
2c: overhang portion
10: supplier
11: sheet
12: supply stage
13: stage moving mechanism
20: pickup device
21: pickup nozzle
22: nozzle moving mechanism
23: direction changer
24: push-up pin
30: mounting device
31, T: tool
32: tool moving mechanism
50: controller
51: supplier control unit
52: push-up pin control unit
53: pickup nozzle control unit
54: tool control unit
56: substrate stage control unit
57: memory
60: substrate stage
61: stage moving mechanism
221: sliding mechanism
221a: support frame
221b: rail
221c: slider
222: elevation mechanism
241: backup body
311: holder
311a: holding surface
311b: outer edge
312: expanded portion
312A: opposing surface
313: first opening
314: first ventilation path
315: second opening
316: second ventilation path
321: sliding mechanism
321a: support frame
321a: rail
321c: slider
322: elevation mechanism
322A: detector
400: negative pressure generation device
410: piping
420: switch
430: piping
440: adjuster
H: suction hole
P1: supply position
P2: deliver position
P3: mounting position

What is claimed is:

1. A mounting tool to mount a rectangular electronic component on a substrate, comprising:
a holder including a holding surface configured to hold an inner side of the electronic component inside a pair of opposite outer edges of the electronic component;
an expanded portion including an opposing surface that is facing away from an overhang portion of the electronic component that protrudes outward than the outer edge of the holding surface of the holder and is not held by the holder;
a first opening provided in the holding surface;
a second opening provided in the opposing surface;
a first ventilation path configured to communicate with the first opening and to suck and hold the electronic component at the holding surface by creating negative internal pressure; and
a second ventilation path configured to communicate with the second opening and to suck the overhang portion of the electronic component facing the opposing surface by creating negative internal pressure.

2. The mounting tool according to claim 1, wherein the opposing surface faces the electronic component sucked by the negative pressure of the second ventilation path so as not to contact with each other.

3. The mounting tool according to claim 1, wherein the holding surface is a flat surface.

4. The mounting tool according to claim 1, wherein the holding surface is a curved surface.

5. The mounting tool according to claim 1, wherein the second opening is a linear groove provided in the expanded portion.

6. The mounting tool according to claim 5, wherein the linear groove is a frame surrounding the holding portion.

7. A mounting apparatus comprising:
a tool moving mechanism configured to move the mounting tool according to any of claim 1 in a direction in which the electronic component contacts with or separate away from a mounting target;
a first switch configured to switch presence or absence of the negative pressure in the first ventilation path; and
a second switch configured to switch presence or absence of the negative pressure in the second ventilation path.

8. The mounting apparatus according to claim 7, further comprising an adjuster to adjust the negative pressure relative to the second ventilation path.

9. The mounting apparatus according to claim 7, further comprising a detector configured to detect a contact of the mounting tool to the substrate,
wherein when the detector detects the contact, the first switch stops the negative pressure of the first ventilation path, and then the tool moving mechanism releases the electronic component while the second switch maintaining the negative pressure of the second ventilation path.

10. The mounting apparatus according to claim 7, further comprising a detector configured to detect a contact to the mounting tool,
wherein when the detector detects the contact, the first switch stops the negative pressure of the first ventilation path, and then the second switch stops the negative pressure of the second ventilation path, and the tool moving mechanism releases the electronic component.
